(19) United States
(12) Patent Application Publication
(10) Pub. No.: US 2026/0211047 A1
(43) Pub. Date: Jul. 23, 2026

(54) BATTERY SYSTEM

(71) Applicant: TOYOTA JIDOSHA KABUSHIKI KAISHA, Toyota-shi (JP)

(72) Inventors: Yohji TAGAMI, Toyota-shi (JP); Kazuyasu IWATA, Toyohashi-shi (JP); Yuki YOSHIKAWA, Toyota-shi (JP)

(73) Assignee: TOYOTA JIDOSHA KABUSHIKI KAISHA, Toyota-shi (JP)

(21) Appl. No.: 19/379,716

(22) Filed: Nov. 4, 2025

(30) Foreign Application Priority Data
Jan. 17, 2025 (JP) 2025-006692

(51) Int. Cl. G01R 31/385; H01M 10/615; H01M 10/625; H01M 10/637; H01M 10/0525

(52) U.S. Cl. CPC G01R 31/385; H01M 10/615; H01M 10/625; H01M 10/637; H01M 10/0525

(57) ABSTRACT

A battery system includes a current sensor that detects a ripple current, and an ECU. The ECU reconstructs, based on an attenuation curve, the actual amplitude of the ripple current flowing through the current sensor from the amplitude of the ripple current detected by the current sensor. When the reconstructed amplitude is greater than the upper limit of the amplitude of the ripple current at which lithium deposition in a battery can be suppressed, the ECU reduces the amplitude of the ripple current.

### CROSS-REFERENCE TO RELATED APPLICATION

This application claims priority to Japanese Patent Application No. 2025-006692 filed on January 17, 2025. The disclosure of the above-identified application, including the specification, drawings, and claims, is incorporated by reference herein in its entirety.

### BACKGROUND

### Technical Field

The present disclosure relates to battery systems.

### Description of Related Art

Japanese Unexamined Patent Application Publication No. 2010-259217 (JP 2010-259217 A) describes a drive device that warms a battery by passing a ripple current through the battery. In this drive device, increasing the ripple current facilitates the warming of the battery.

### SUMMARY

However, in a case where the battery includes lithium-ion cells, lithium deposition may occur when the amplitude of the ripple current exceeds a predetermined threshold. One possible approach is to reduce the amplitude of the ripple current such that the value (amplitude) detected by the current sensor remains at or below the predetermined threshold. In practice, however, the value (amplitude) detected by the current sensor may be attenuated relative to the actual amplitude of the ripple current. In such cases, lithium deposition may still occur.

The present disclosure has been made to address this issue, and an object thereof is to provide a battery system that can suppress lithium deposition in an energy storage device including lithium-ion cells.

A battery system according to one aspect of the present disclosure includes: a ripple generation device connected to an energy storage device including lithium-ion cells, and configured to generate a ripple current in the energy storage device; a current detection device configured to detect the ripple current generated by the ripple generation device; and a control device configured to control the ripple generation device. An upper limit of an amplitude of the ripple current at which suppression of lithium deposition in the energy storage device is possible is defined as an upper limit amplitude, and a curve indicating a relationship between an attenuation ratio and a frequency of the ripple current is defined as an attenuation curve. The attenuation ratio is a ratio of a first amplitude that is an actual amplitude of the ripple current flowing through the current detection device to a second amplitude that is an amplitude of the ripple current detected by the current detection device. The control device is configured to reconstruct, based on the attenuation curve, the first amplitude from the second amplitude of the ripple current detected by the current detection device, and when a reconstructed amplitude that is the reconstructed first amplitude is greater than the upper limit amplitude, reduce the amplitude of the ripple current.

In the battery system according to the aspect of the present disclosure, as described above, the control device reconstructs, based on the attenuation curve, the first amplitude from the second amplitude of the ripple current detected by the current detection device. When the reconstructed amplitude, namely the reconstructed first amplitude, is greater than the upper limit amplitude, the control device reduces the amplitude of the ripple current. Accordingly, even when the detected value from the current detection device is attenuated, the amplitude is reconstructed using the attenuation curve. In this way, the amplitude of the ripple current actually flowing through the current detection device can be adjusted so as not to exceed the upper limit amplitude. As a result, lithium deposition in the energy storage device can be suppressed.

The control device may be configured to, when the reconstructed amplitude is greater than the upper limit amplitude, reduce the amplitude of the ripple current such that the reconstructed amplitude becomes equal to, or substantially equal to, the upper limit amplitude. With this configuration, lithium deposition in the energy storage device can be easily suppressed. In addition, the amplitude of the ripple current can be made relatively large while suppressing lithium deposition. As a result, the overall temperature rise of the energy storage device caused by the ripple current can be made more efficient.

The control device may be configured to, when the reconstructed amplitude is less than or equal to the upper limit amplitude, keep the amplitude of the ripple current unchanged at its current value. With this configuration, lithium deposition in the energy storage device can be easily suppressed.

The current detection device may include a busbar and a magnetic field detection element configured to detect a magnetic field generated by a current flowing through the busbar. The busbar may have a rectangular cross section that intersects a direction in which the current flows. Due to the skin effect, the current density near the center of the cross section of the busbar becomes relatively small. As a result, when the busbar has a rectangular cross section, the magnetic field generated by the ripple current flowing through the busbar becomes non-uniform (the magnetic field becomes concentrated at the ends). Therefore, the magnetic field input to the magnetic field detection element decreases, and consequently, the current value detected by the current sensor may be attenuated. Accordingly, reducing the amplitude of the ripple current based on the amplitude reconstructed using the attenuation curve is particularly effective when the busbar has a rectangular cross section.

In addition, since the cross section has a rectangular shape, the area of the cross section can be more easily made larger than when, for example, the cross section has a square shape. As a result, the ripple current that can be passed through the busbar can be easily increased.

The control device may be configured to adjust the frequency of the ripple current. The current detection device may be configured to detect the second amplitude corresponding to each of a plurality of frequencies within a predetermined frequency range including a target value of the frequency. The control device may be configured to calculate, based on the second amplitudes corresponding to the frequencies, a rate of change of the second amplitude with respect to the frequency in the frequency range, and determine, based on the attenuation curve, whether the rate of change is abnormal. The control device may be configured to, when determination is made that the rate of change is abnormal, stop generation of the ripple current, and when determination is made that the rate of change is not abnormal, set the frequency to the target value. The control device may be configured to calculate the reconstructed amplitude based on the attenuation curve and the second amplitude corresponding to the target value, and when the reconstructed amplitude is greater than the upper limit amplitude, reduce the amplitude of the ripple current. With this configuration, it is possible to suppress execution of the process of reducing the amplitude of the ripple current based on the reconstructed amplitude when the frequency of the ripple current deviates from the target value.

With the present disclosure, it is possible to suppress lithium deposition in an energy storage device including lithium-ion cells.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing a vehicle equipped with a battery system according to an embodiment of the present disclosure;

FIG. 2 is a schematic diagram showing the configuration of a battery according to the embodiment;

FIG. 3 is a graph showing an attenuation curve of a current sensor;

FIG. 4 is a flowchart showing control performed by the battery system according to the embodiment;

FIG. 5 is a flowchart showing details of step S20 of FIG. 4; and

FIG. 6 is a flowchart showing details of step S30 in FIG. 4.

### DETAILED DESCRIPTION OF EMBODIMENTS

An embodiment of the present disclosure will be described in detail with reference to the drawings. The same or corresponding portions are denoted by the same signs throughout the drawings, and description thereof will not be repeated.

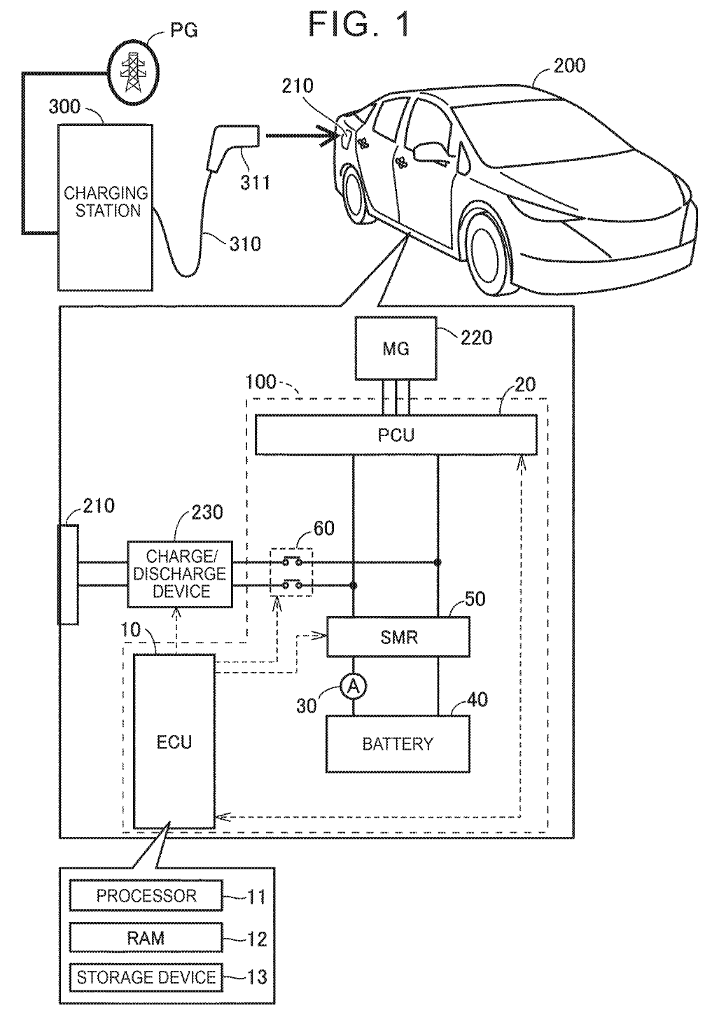

FIG. 1 shows a vehicle 200 equipped with a battery system 100 according to the embodiment of the present disclosure.

The vehicle 200 can transfer electric power to and from a charging station 300 (that is, perform charging and discharging) when electrically connected to the charging station 300 through a cable 310. This power transfer takes place when a plug 311 provided at the end of the cable 310 is connected to an inlet 210 of the vehicle 200. Alternating current flows between the charging station 300 and the vehicle 200. The charging station 300 transfers electric power to and from a power grid PG.

The vehicle 200 is equipped with the battery system 100, a motor generator (MG) 220, and a charge/discharge device 230.

The battery system 100 includes an electronic control unit (ECU) 10, a power control unit (PCU) 20, a current sensor 30, a battery 40, a system main relay (SMR) 50, and a relay 60. The ECU 10 and the battery 40 are examples of the "control device" and the "energy storage device" in the present disclosure, respectively. The PCU 20 and the current sensor 30 are examples of the "ripple generation device" and the "current detection device" in the present disclosure, respectively.

The ECU 10 includes a processor 11, a random access memory (RAM) 12, and a storage device 13. The storage device 13 is configured to retain stored information. The storage device 13 stores programs and information to be used by the programs (for example, maps, formulas, and various parameters). In the present embodiment, the processor 11 executes the programs stored in the storage device 13, enabling the ECU 10 to perform various processes (such as ripple current control described later). These processes may be executed solely by hardware (electronic circuits) without using software.

The vehicle 200 is configured to run on electric power stored in the battery 40. The vehicle 200 may be, for example, a battery electric vehicle (BEV) without an engine (internal combustion engine). However, the vehicle 200 is not limited to a BEV, and may be a plug-in hybrid electric vehicle (PHEV) equipped with an internal combustion engine, or another type of electrified vehicle (xEV).

The charge/discharge device 230 and the relay 60 are positioned between the inlet 210 and the battery 40. The charge/discharge device 230 and the relay 60 are controlled by the ECU 10. In the present embodiment, a charge/discharge line including the inlet 210, the charge/discharge device 230, and the relay 60 is connected between the SMR 50 and the PCU 20. However, the charge/discharge line is not limited to this and may be connected between the battery 40 and the SMR 50.

The charge/discharge device 230 charges the battery 40 using electric power supplied from outside the vehicle through the inlet 210. The charge/discharge device 230 includes a power conversion circuit (for example, a converter including an inverter and a reactor) and is configured to adjust the charging current. The relay 60 selectively connects and disconnects the electrical path between the inlet 210 and the battery 40.

When in a plugged-in state, the vehicle 200 can perform external charging (i.e., charging the battery 40 using electric power supplied from outside the vehicle) and external discharging (i.e., discharging the battery 40 to the outside of the vehicle). The vehicle 200 may alternatively be configured to perform external charging alone. The relay 60 is closed (connected) when external charging or external discharging is performed and is open (disconnected) when neither external charging nor external discharging is performed.

The MG 220 is, for example, a three-phase alternating current motor generator. The MG 220 functions as a traction motor for the vehicle 200. The MG 220 is driven by the PCU 20 to rotate the drive wheels of the vehicle 200. The MG 220 also performs regenerative power generation and outputs the generated electric power to the battery 40. Any number of traction motors may be provided in the vehicle 200.

The PCU 20 includes a circuit (for example, an inverter and a converter) that drives the MG 220 using electric power supplied from the battery 40. The SMR 50 selectively connects and disconnects the electrical path between the battery 40 and the PCU 20. The SMR 50 and the PCU 20 are controlled by the ECU 10. The SMR 50 is closed (connected) when the vehicle 200 is traveling. The SMR 50 is also closed when electric power is transferred between the battery 40 and the inlet 210 (and therefore the outside of the vehicle).

The battery 40 includes a plurality of energy storage cells (not shown). The energy storage cells are secondary cells, typically lithium-ion secondary cells. Lithium-ion secondary cells use lithium as the charge carrier and may include not only lithium-ion secondary cells using a liquid electrolyte but also all-solid-state cells using a solid electrolyte.

The ripple current may be generated by the PCU 20 under control of the ECU 10. Specifically, the ripple current is generated when a switching element provided in the PCU 20 is switched by the ECU 10. The ECU 10 may be configured to adjust the frequency of the ripple current by adjusting the on-off cycle of the switching element. The method for generating the ripple current is not limited to this example.

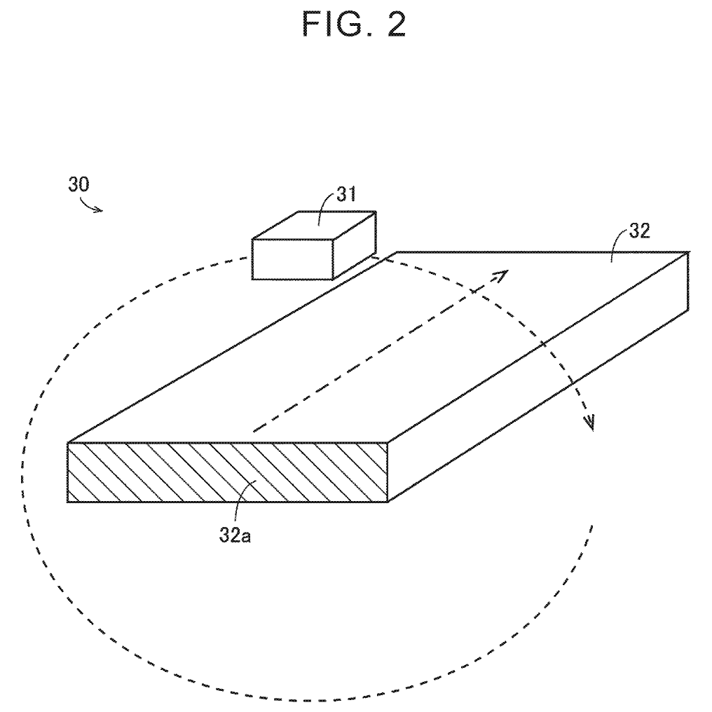

FIG. 2 is a schematic diagram showing the configuration of the current sensor 30. The current sensor 30 detects the current flowing between the battery 40 and the SMR 50.

The current sensor 30 includes a magnetic field detection element 31 and a busbar 32. The current (ripple current) flows through the busbar 32 in the direction of an arrow indicated by a long-dashed, short-dashed line in FIG. 2. In this case, a magnetic field (shown by a dashed arrow) is formed by the current flowing through the busbar 32. As shown in FIG. 2, the busbar 32 has a rectangular cross section 32a that intersects (is perpendicular to) the direction in which the current flows. For example, the length of the long side of the cross section 32a may be five times or more the length of the short side of the cross section 32a.

Due to the skin effect, the current near the center of the cross section 32a decreases as the frequency of the ripple current increases. Accordingly, the higher the frequency of the ripple current, the greater the non-uniformity of the magnetic field generated by the ripple current. As a result, the magnetic field input to the magnetic field detection element 31 decreases, and consequently, the current value detected by the current sensor 30 is attenuated.

The current value detected by the current sensor 30 is also attenuated by low-pass filters (not shown) provided in each of the current sensor 30 and the ECU 10. The amount of attenuation caused by the low-pass filters increases as the frequency of the ripple current increases.

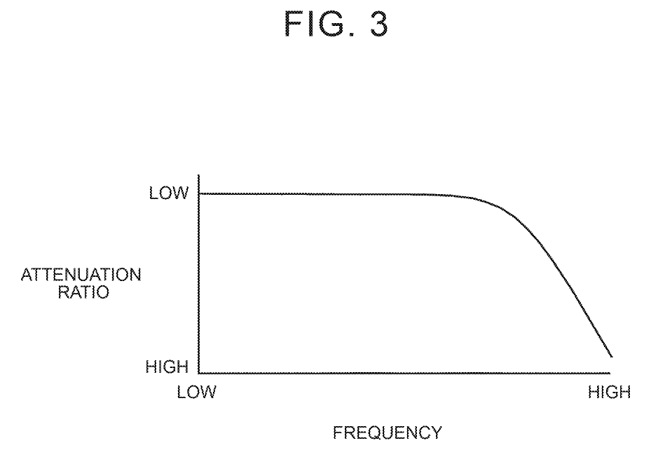

FIG. 3 is an attenuation curve showing the relationship between the frequency of the ripple current (horizontal axis) and the attenuation ratio of the current sensor 30 (vertical axis). The attenuation ratio refers to the ratio of the amplitude detected by the current sensor 30 to the actual amplitude of the ripple current flowing through the current sensor 30 (busbar 32). The data on this attenuation curve may be stored in the storage device 13 of the ECU 10. As shown in FIG. 3, the attenuation ratio of the current sensor 30 increases as the frequency of the ripple current increases.

In lithium-ion cells, lithium deposition may occur when the amplitude of the ripple current exceeds a predetermined threshold. One possible approach is to reduce the amplitude of the ripple current such that the value (amplitude) detected by the current sensor remains at or below the predetermined threshold. In practice, however, the value (amplitude) detected by the current sensor may be attenuated relative to the actual amplitude of the ripple current. In such cases, lithium deposition may still occur.

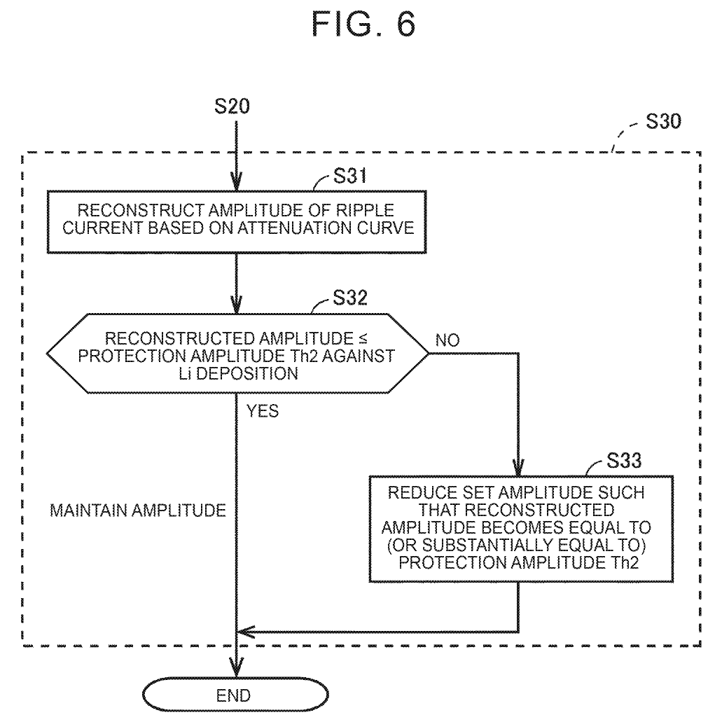

Accordingly, in the present embodiment, the ECU 10 calculates the actual (pre-attenuation) amplitude based on the attenuation curve and the amplitude of the ripple current detected by the current sensor 30. When the calculated amplitude (hereinafter referred to as the "reconstructed amplitude") exceeds the upper limit of the amplitude at which lithium deposition is suppressed (hereinafter referred to as the "upper limit amplitude"), the ECU 10 reduces the amplitude of the ripple current. This will be described in detail later with reference to FIG. 6.

### Control Flow

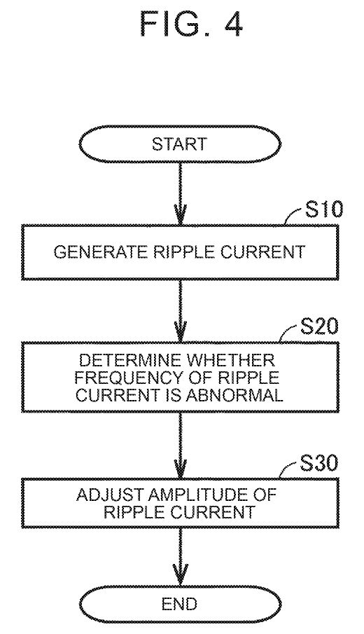

FIG. 4 is a flowchart showing control performed by the ECU 10. The control flow shown in FIG. 4 is executed when the battery 40 is warmed by the ripple current.

In step S10, the ECU 10 generates the ripple current by controlling the PCU 20, the SMR 50, the relay 60, and the like. At this time, the ECU 10 sets the frequency of the ripple current to a predetermined target value (for example, 1000Hz). The process then proceeds to step S20.

In step S20, the ECU 10 determines whether the frequency of the ripple current is abnormal. The process then proceeds to step S30.

In step S30, the ECU 10 adjusts the amplitude of the ripple current. The process then ends.

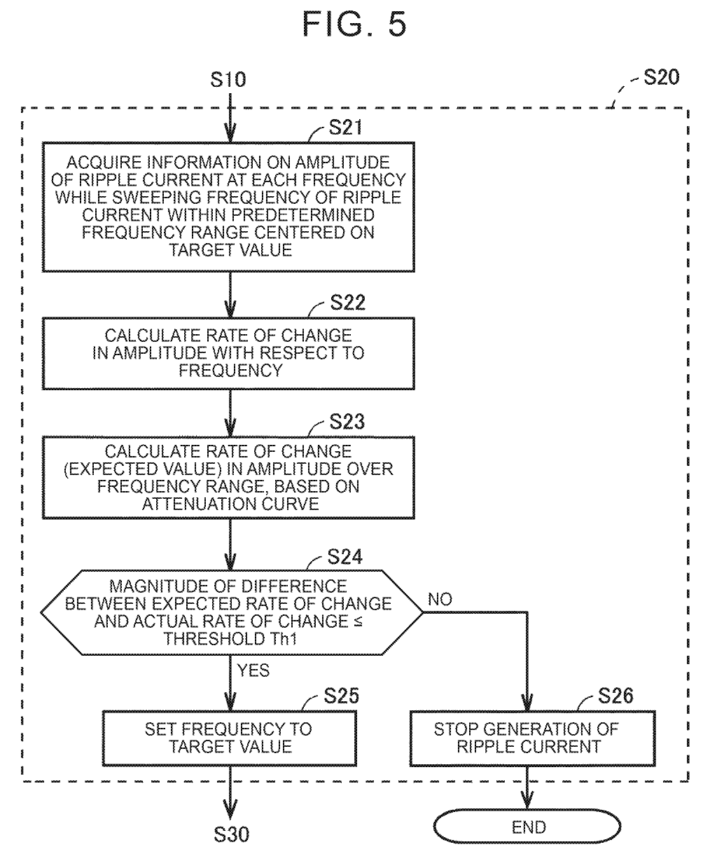

FIG. 5 is a flowchart showing details of step S20. Step S20 includes steps S21 to S26.

In step S21, the ECU 10 acquires from the current sensor 30, information on the amplitude of the ripple current at each frequency while sweeping (changing) the frequency of the ripple current within a predetermined frequency range centered on the target value. For example, with the amplitude of the ripple current set to a predetermined value (for instance, 500A), the ECU 10 acquires from the current sensor 30, amplitude information at frequencies of 900 Hz, 1000 Hz (target value), and 1100 Hz.

In step S22, the ECU 10 calculates the rate of change in amplitude with respect to frequency, based on the information acquired from the current sensor 30. Specifically, the ECU 10 calculates the rate of change from the change in amplitude (detected value) over the frequency range from 900 Hz to 1100 Hz. The ECU 10 may calculate the rate of change using, for example, the least-squares method.

In step S23, the ECU 10 calculates the rate of change (expected value) in amplitude over the above frequency range, based on the attenuation curve. For example, suppose that the attenuation ratio is 30% at 900 Hz, 35% at 100 Hz, and 40% at 1100 Hz, based on the attenuation curve. In that case, when the amplitude is set to 500A, the rate of change is calculated as (500 × 0.7 − 500 × 0.6)/(900 − 1100) = −0.25.

In step S24, the ECU 10 determines whether the magnitude (absolute value) of the difference between the rate of change (expected value) calculated in step S23 and the rate of change calculated in step S22 is less than or equal to a threshold Th1. When the difference is less than or equal to the threshold Th1 (Yes in step S23), the process proceeds to step S25. When the difference is greater than the threshold Th1 (No in step S23), the process proceeds to step S26.

The threshold Th1 may vary depending on the set amplitude and the frequency. For example, the larger the set amplitude and the higher the frequency, the larger the threshold Th1 may be. The threshold Th1 may be calculated by computation performed by the ECU 10 or may be determined by the ECU 10 based on a map showing the relationship between the set amplitude and frequency and the threshold Th1.

In step S25, the ECU 10 sets the frequency of the ripple current to the target value (1000 Hz in the present embodiment). The process then proceeds to step S30.

In step S26, the ECU 10 stops generation of the ripple current. Specifically, the ECU 10 may stop generation of the ripple current by stopping switching of the switching element provided in the PCU 20. The process then ends.

FIG. 6 is a flowchart showing details of step S30. Step S30 includes steps S31 to S33.

In step S31, the ECU 10 reconstructs the amplitude of the ripple current based on the attenuation curve. When the attenuation ratio is 35% at 1000 Hz based on the attenuation curve as described above, the ECU 10 may reconstruct the amplitude by multiplying the amplitude detected by the current sensor 30 by 100/65.

In step S32, the ECU 10 determines whether the amplitude reconstructed in step S31 is less than or equal to a protection amplitude Th2 against lithium deposition. The protection amplitude Th2 is the upper limit of the amplitude at which lithium deposition in the battery 40 can be suppressed. When the reconstructed amplitude is less than or equal to the protection amplitude Th2 (Yes in step S32), the process ends. In this case, the ECU 10 keeps the amplitude of the ripple current unchanged at its current value. When the reconstructed amplitude is greater than the protection amplitude Th2 (No in step S32), the process proceeds to step S33. In step S31, the protection amplitude Th2 may be set to a different value depending on the frequency. Data such as a map indicating the relationship between the protection amplitude Th2 and the frequency, as used in step S31, may be stored in the storage device 13 (FIG. 1).

In step S33, the ECU 10 reduces the set amplitude such that the reconstructed amplitude becomes equal to, or substantially equal to, the protection amplitude Th2. For example, the ECU 10 may gradually reduce the amplitude of the ripple current until the reconstructed amplitude reaches the protection amplitude Th2 or a value substantially equal to the protection amplitude Th2. The process then ends. Here, "substantially equal to the protection amplitude Th2" may refer to, for example, a range that is greater than or equal to a predetermined percentage (e.g., 95%) of the protection amplitude Th2 and less than the protection amplitude Th2. The reduction of the amplitude of the ripple current may be implemented by any known method.

As described above, in the present embodiment, the ECU 10 reconstructs the actual amplitude of the ripple current flowing through the current sensor 30 from the amplitude of the ripple current detected by the current sensor 30, based on the attenuation curve. When the reconstructed amplitude is greater than the upper limit amplitude, the ECU 10 reduces the amplitude (set amplitude) of the ripple current. As a result, even when the detected value from the current sensor 30 is attenuated relative to the actual amplitude, lithium deposition in the battery 40 can be suppressed.

### Modifications

The above embodiment illustrates an example in which, when the reconstructed amplitude is greater than the upper limit amplitude, the amplitude of the ripple current is reduced such that the reconstructed amplitude becomes equal to, or substantially equal to, the upper limit amplitude. However, the present disclosure is not limited to this. For example, in such a case, the amplitude of the ripple current may instead be reduced such that the reconstructed amplitude becomes smaller than the upper limit amplitude by a predetermined amount.

The above embodiment illustrates an example in which, when the reconstructed amplitude is less than or equal to the upper limit amplitude, the amplitude of the ripple current is not changed. However, the present disclosure is not limited to this. In such a case, the amplitude of the ripple current may instead be increased such that the reconstructed amplitude becomes equal to, or substantially equal to, the upper limit amplitude.

The above embodiment illustrates an example in which the busbar 32 of the current sensor 30 has the rectangular cross section 32a. However, the present disclosure is not limited to this. The cross section of the busbar may have a shape other than rectangular (for example, circular or square).

The above embodiment illustrates an example in which whether the rate of change in the amplitude of the ripple current is abnormal is determined based on the detected values from the current sensor 30 corresponding to multiple frequencies. However, the present disclosure is not limited to this. The determination may instead be made based on the detected value from the current sensor 30 corresponding to a single frequency (the target value).

The above embodiment illustrates an example in which the ripple current is generated by controlling the switching element of the PCU 20. However, the present disclosure is not limited to this. For example, the ripple current may instead be generated by controlling a switching element of the charge/discharge device 230.

The above embodiment illustrates an example in which the current sensor 30 that detects a current value based on the magnitude of a magnetic field is provided. However, the present disclosure is not limited to this. A current sensor that detects a current value based on the magnitude of a voltage drop across a shunt resistor may be provided.

The configurations of the above embodiment and modifications may be combined with each other.

The embodiment disclosed herein should be considered to be illustrative in all respects and not restrictive. The scope of the present disclosure is set forth in the claims rather than in the above description of the embodiment and is intended to include all modifications within the meaning and scope equivalent to the claims.

What is claimed is:

1. A battery system comprising:
a ripple generation device connected to an energy storage device including lithium-ion cells, the ripple generation device being configured to generate a ripple current in the energy storage device;
a current detection device configured to detect the ripple current generated by the ripple generation device; and
a control device configured to control the ripple generation device, wherein:
an upper limit of an amplitude of the ripple current at which suppression of lithium deposition in the energy storage device is possible is defined as an upper limit amplitude, and a curve indicating a relationship between an attenuation ratio and a frequency of the ripple current is defined as an attenuation curve, the attenuation ratio being a ratio of a first amplitude that is an actual amplitude of the ripple current flowing through the current detection device to a second amplitude that is an amplitude of the ripple current detected by the current detection device; and
the control device is configured to
reconstruct, based on the attenuation curve, the first amplitude from the second amplitude of the ripple current detected by the current detection device, and
when a reconstructed amplitude that is the reconstructed first amplitude is greater than the upper limit amplitude, reduce the amplitude of the ripple current.

2. The battery system according to claim 1, wherein the control device is configured to, when the reconstructed amplitude is greater than the upper limit amplitude, reduce the amplitude of the ripple current such that the reconstructed amplitude becomes equal to, or substantially equal to, the upper limit amplitude.

3. The battery system according to claim 1, wherein the control device is configured to, when the reconstructed amplitude is less than or equal to the upper limit amplitude, keep the amplitude of the ripple current unchanged at a current value.

4. The battery system according to claim 1, wherein:
the current detection device includes
a busbar, and
a magnetic field detection element configured to detect a magnetic field generated by a current flowing through the busbar; and
the busbar has a rectangular cross section that intersects a direction in which the current flows.

5. The battery system according to claim 1, wherein:
the control device is configured to adjust the frequency of the ripple current;
the current detection device is configured to detect the second amplitude corresponding to each of a plurality of frequencies within a predetermined frequency range including a target value of the frequency; and
the control device is configured to
calculate, based on the second amplitudes corresponding to the frequencies, a rate of change of the second amplitude with respect to the frequency in the frequency range,
determine, based on the attenuation curve, whether the rate of change is abnormal,
when determination is made that the rate of change is abnormal, stop generation of the ripple current,
when determination is made that the rate of change is not abnormal, set the frequency to the target value, and
calculate the reconstructed amplitude based on the attenuation curve and the second amplitude corresponding to the target value, and when the reconstructed amplitude is greater than the upper limit amplitude, reduce the amplitude of the ripple current.
